(19) United States
(12) Patent Application Publication
(10) Pub. No.: US 2025/0110194 A1
(43) Pub. Date: Apr. 3, 2025

(54) Recording Magnetic Resonance Data of an Object Under Examination Comprising Spins of at Least Two Different Spin Species

(71) Applicant: Siemens Healthineers AG, Forchheim (DE)

(72) Inventor: Alto Stemmer, Uttenreuth (DE)

(73) Assignee: Siemens Healthineers AG, Forchheim (DE)

(21) Appl. No.: 18/899,018

(22) Filed: Sep. 27, 2024

(30) Foreign Application Priority Data
Sep. 29, 2023 (DE) 10 2023 209 597.1

(51) Int. Cl. G01R 33/561; G01R 33/54; G01R 33/56

(52) U.S. Cl. CPC G01R 33/5617; G01R 33/543; G01R 33/5608

(57) ABSTRACT

In an MR data recording method, different desired phase differences between spins of a first spin species and spins of a second spin species are generated by irradiated RF excitation pulses in each case and corresponding MR datasets are recorded in respective echo trains after irradiation of the RF excitation pulses. This makes it possible to eliminate the need to shift the readout interval away from the spin-echo time, as was previously necessary to generate different phase differences and the associated extension of echo spacings in order to generate the different phase differences between the spin species. Thus, the disadvantages of a previously necessary extension of the echo spacing can be avoided with the method according to the disclosure.

### CROSS REFERENCE TO RELATED APPLICATIONS

This patent application claims priority to German Patent Application No. 10 2023 209 597.1, filed Sep. 29, 2023, which is incorporated herein by reference in its entirety.

### BACKGROUND

### Field

The disclosure relates to the recording of magnetic resonance data of an object under examination comprising spins of at least two different spin species.

### Related Art

Magnetic resonance technology (hereinafter, the abbreviation MR stands for magnetic resonance) is a known technology which can be used to generate images of the inside of an object under examination. In simple terms, for this purpose, the object under examination is placed in a magnetic resonance device in a comparatively strong static homogeneous main magnetic field, also called the B0 field, with field strengths of 0.2 tesla to 7 tesla and more, such that the nuclear spins of the object are oriented along the main magnetic field. In order to trigger nuclear spin resonances that can be measured as signals, radio-frequency excitation pulses (RF pulses) are irradiated into the object under examination and the triggered nuclear spin resonances are measured in the frequency space as so-called k-space data and used as the basis for reconstructing MR images or ascertaining spectroscopic data. The alternating magnetic field generated by the excitation pulses radiated by means of a transmission coil is also referred to as the B1 field. For spatial encoding of the measurement data, rapidly switched magnetic gradient fields, gradients for short, are superimposed on the main magnetic field. One scheme used which describes a temporal sequence of RF pulses to be irradiated and gradients to be switched is referred to as a pulse sequence (scheme), or sequence for short. The recorded measurement data is digitized and saved as complex numerical values in a k-space matrix. An associated MR image can be reconstructed from the k-space matrix occupied by values, for example by means of a multi-dimensional Fourier transform.

In a magnetic resonance system, the measurable volume of a magnetic resonance recording is limited in all three spatial directions due to physical and technical conditions, such as, for example, limited magnetic field homogeneity and non-linearity of the gradient field. Therefore, a recording volume, a so-called “field of view” (FoV), is limited to a volume in which the aforementioned physical features lie within a predetermined tolerance range and thus true-to-scale mapping of the object to be examined is possible with conventional measurement sequences. However, in particular in the x- and y-directions, i.e., perpendicular to a longitudinal axis of a tunnel of the magnetic resonance system, the field of view limited in this way is considerably smaller than the volume limited by the annular tunnel of the magnetic resonance system. With conventional magnetic resonance systems, the diameter of the annular tunnel is, for example, approximately 60 cm, whereas the diameter of the conventionally used field of view, in which the above-mentioned physical features are within the tolerance range, is approximately 50 cm.

The most commonly used method for generating echo signals after excitation of the nuclear spins is the so-called spin echo method. Herein, in the simplest case, the transverse magnetization is so to speak “flipped” by irradiating at least one RF refocusing pulse after the irradiation of the RF excitation pulse, whereby the dephased magnetization is rephased again and thus a so-called spin echo SE is formed at a time after a time TE known as the echo time after the RF excitation pulse.

The excitation and measurement of the generated echo signals are repeated after a repetition time TR (for example by switching different gradients for spatial encoding) until the desired number of echo signals has been measured and stored in the k-space in order to be able to map the object under examination.

SE sequences, in particular TSE sequences (TSE: turbo spin echo), also known as FSE (fast spin echo) or RARE (rapid acquisition with refocused echoes) sequences are widely used in clinical applications. The advantage of TSE sequences over “simple” SE sequences is that a plurality of refocusing pulses is switched after an RF excitation pulse and that, as a result, a plurality of spin echo signals SE that can be individually coded is generated after excitation so that a plurality of k-space lines can be scanned after an RF excitation pulse, for example. This speeds up data recording, since fewer repetitions of the sequence with different spatial encoding are required to measure all the desired data. The measurement time for the entire k-space is thus reduced for TSE sequences according to the number of echo signals refocused and recorded after excitation, the so-called “turbo factor”, compared to conventional SE methods. Herein, the plurality of echo signals generated after a common RF excitation pulse is also referred to as an echo train and the time interval between two echo signals of an echo train is referred to as the echo spacing.

However, since 180° pulses are traditionally used for refocusing pulses, TSE sequences can generate high SAR exposure (SAR: specific absorption rate). However, it is also possible to use smaller flip angles for the refocusing pulses without significantly reducing the signal intensity, wherein a so-called “pseudo steady state” is generated. This is described, for example, in the article by Alsop “The Sensitivity of Low Angle RARE Imaging”, Magnetic Resonance in Medicine, 37, 1997, pp 176-184. In addition, the way in which the flip angle can be specifically manipulated is, for example, described by Hennig et al. in “Multiecho Sequences with Variable Refocusing Flip Angles: Optimization of Signal Behavior Using Smooth Transitions between Pseudo Steady States (TRAPS)”; Proc. Intl. Soc. Mag. Reson. Med. 10, 2002, p 2356.

In the conventional approach, images of the inside of an object are recorded slice-by-slice. Herein, in each case a relatively thin slice, usually between 1 and 5 mm, is selectively excited. Such selective excitation is achieved by applying a gradient in the slice-selection direction in a coordinated manner with an irradiated exciting RF pulse. Such a pulse arrangement (consisting of the exciting RF pulse and the associated gradient) ensures that the RF pulse only acts selectively on the region determined by the gradient and the RF pulse. In most cases, this slice-selection direction runs parallel to the so-called z-axis, the longitudinal axis of the magnetic resonance system or also to the longitudinal axis of a patient lying in the magnetic resonance system. Spatial encoding within a slice then takes place on the one hand by phase encoding in a direction perpendicular to the slice-selection direction (generally, the y-direction) and by readout encoding in the second direction perpendicular to the slice-selection direction (generally the x-direction). This enables a two-dimensional k-space to be filled by entering the measured measurement as raw data at the corresponding k-space points. An image of the slice can be generated therefrom by a two-dimensional Fourier transform.

There is also the possibility of exciting larger three-dimensional volumes and measuring them in a 3D method. Herein, instead of a thin slice, now a relatively thick slice (typically referred to as a “slab”) is excited in an excitation process. However, these slabs, which are generally more than 10 mm thick, must be measured once again in a spatially resolved manner in the slice-selection direction when raw data is recorded. This is usually done by means of a second phase encoding, i.e. with this method, measurements are carried out in a phase encoded manner in two directions and in a read-out encoded manner in one direction in order thus to fill a three-dimensional k-space with raw data and to generate a three-dimensional image volume therefrom by means of a 3D Fourier transform.

For example, the SPACE sequence (“sampling perfection with application optimized contrasts using different flip angle evolutions”; also called “CUBE” or “VISTA”) makes it possible to create high-resolution three-dimensional (3D) images in a short time. The SPACE sequence is a 3D turbo spin echo (TSE) sequence with short (spatially) non-selective RF refocusing pulses with application-specific (for example, optimized for a desired contrast) variable flip angles, which allow a shortening of the echo spacing within an echo train and long echo train lengths.

A specific problem with such 3D TSE techniques with short non-selective RF refocusing pulses with application-specific variable flip angles are so-called FID artifacts (FID: free induction decay). FID artifacts occur when longitudinal magnetization, which has arisen, for example, due to T1 relaxation (return of the magnetization tilted by the excitation pulse into the transverse plane in the longitudinal direction; also referred to as decay of the longitudinal magnetization) during the echo train is excited by an RF refocusing pulse with a flip angle of <180° into the transverse plane. For example, the article by Mugler “Optimized Three-Dimensional Fast-Spin-Echo MRI”, J. Magn. Reson. Imaging 39: pp 745-767, 2014, describes the problem of FID artifacts for 3D TSE techniques.

These FID artifacts can be avoided by acquiring each echo train twice, i.e., in two repetitions, wherein the phase of the RF refocusing pulses varies by 180° between the repetitions. Such a variation of the phase of the RF refocusing pulses between two echo trains or also during an echo train is also referred to as a “phase-cycling” scheme. If such a phase-cycling scheme is used to eliminate FID artifacts, the minimum number of echo trains to be recorded, and thus the total acquisition time required for all repetitions is doubled, provided that the sequence parameters that determine contrast and resolution are left unchanged.

A characteristic of T2 weighted TSE techniques (T2: decay constant of the decay of the transverse magnetization) is that fat (lipid) signals appear bright in reconstructed images. Since a bright fat signal can make the detection of lesions more difficult, techniques are known for suppressing fat signals.

Protons in different (chemical) environments are also referred to as different spin species. Different environments shield the B0 field to different degrees, which creates a different magnetic field at the nucleus, so that different spin species precess differently leading to different resonance frequencies. This is also referred to as a chemical shift between the different spin species. This leads to different phase angles of the captured signals when recording the signal, unless specific measures, such as the formation of a spin echo, are implemented. The most prominent representatives of two different spin species are fat and water, wherein, however, other applications are possible. The resonance frequency of protons bound to lipid molecules, which are assigned to the spin species “fat”, is about 3.3-3.5 ppm (parts per million) lower than the resonance frequency of protons bound to water, which are assigned to the spin species “water”.

This fact can be used to suppress the bright fat signal with frequency-selective RF saturation or RF inversion pulses that are switched before a subsequent TSE echo train. One disadvantage of such a fat suppression technique with frequency-selective RF saturation or RF inversion pulses is that these techniques are based on a homogeneous B0 field. Despite shimming techniques for homogenizing the B0 field, it is generally not possible to establish a truly homogeneous B0 field in the entire imaging volume, which means that fat suppression is incomplete and unwanted water suppression can occur.

As an alternative to such spectral saturation or inversion, the phase information of recorded MR signals can be used to separate the signals of two different spin species, as is the case with so-called chemical shift imaging (CSI). CSI is also known as the Dixon technique. The Dixon technique makes it possible to separate the signals of the fat and water components of the tissue into separate images. The Dixon technique can be used for fat suppression (diagnosis based on the pure water images) or for fat-water quantification in which the local fat content of the tissue is determined. The article by Eggers and Bornert “Chemical Shift Encoding-Based Water-Fat Separation Methods”, J. Magn. Reson. Imaging 40: pp 251-268, 2014, gives an overview of CSI.

In Dixon techniques, at least two MR datasets are in each case recorded at different echo times after excitation. Herein, the echo times are selected such that the relative phase position of different spin species of the signals contained in an MR dataset is different in the different MR datasets recorded. This means that, in at least one of the recorded MR datasets, the phase position of one of the spin species contained in the MR dataset is different relative to another spin species contained in the MR dataset than in at least one other recorded MR dataset. With knowledge of the respective phase positions, combination images can be extracted from the recorded MR datasets and the complex MR image datasets reconstructed therefrom, which, for example, only represent signals from one spin species.

In principle, a Dixon reconstruction uses a plurality of complex MR image datasets with different (and known) phase shifts between the different spin species as input. The number of MR image datasets required and the phase shift of the spin species required in each case in these MR image datasets depend on the respective Dixon technique. The conventional 2-point Dixon technique requires, for example, two MR image datasets, a first MR image dataset, often called opposed phase image, with a phase shift of 180° between the spin species, for example the water and fat components; and a second cophasal MR image dataset, often called in-phase image with a phase shift of 0° between the spin species. Modern 2-point Dixon variants allow fat-water separation, even if the MR image datasets do not exactly fulfill the opposed phase condition and/or in-phase condition.

In principle, it is possible to realize a Dixon technique with different sequence types, for example with (turbo) spin echo sequences. It is known to record MR datasets that fulfill the in-phase condition on the one hand and MR datasets that fulfill the opposed-phase condition on the other separately from one another in each case in separate recordings. Examples of TSE Dixon techniques in which data for in-phase and opposed-phase MR datasets are recorded in one echo train (i.e., after excitation) are described in U.S. Pat. No. 10,379,185 B2 or the article by Rydén et al. “RARE two-point Dixon with dual bandwidths”, Magn. Reson. Med. 84: pp. 2456-2468, 2020. However, in the case of non-selective 3D TSE techniques, only one echo train of a certain echo time can be recorded for each RF excitation pulse and repetition time TR.

In any case, a conventional TSE sequence in each case forms echo signals at the mid-point between two consecutive RF refocusing pulses. At this spin echo time, the signals of the different spin species (i.e., for example, water and fat signal) are in phase, i.e., they do not have the phase shift required for the Dixon technique. In order to still be able to use TSE sequences for a Dixon technique, the acquisition window in which an MR dataset is recorded is shifted away from the spin echo time by a time interval Δt. The desired phase angle Δθ, for example between water and fat components as different spin species, determines the time interval Δt as follows:

$$Δ t = \frac{Δ θ}{( 360 ° ) {f}_{c s}} . \qquad ( 1 )$$

Herein, f_{cs} is the chemical shift between the different spin species, for example between a water signal and a fat signal, which is approximately 210 Hz at 1.5 T and approximately 420 Hz at 3 T. For a phase shift of 180° between water and fat components, the time interval Δt is therefore 2.3 milliseconds at 1.5 T or 1.2 milliseconds at 3 T.

In known TSE Dixon techniques, in addition to shifting the acquisition window Δt, the scheme of the gradient to be switched in the read-out direction is modified in such a way that at the time Δt after the spin echo time, the phase accumulated as a result of the readout gradient is zero.

Shifting the acquisition window by Δt extends the echo spacing by 2Δt and dead times usually occur in the TSE sequence during which no signal is acquired or encoded.

The extension of the echo spacing is a disadvantage for every TSE Dixon technique, since a reasonable echo train duration is limited due to the inherent T1/T2 decay and the extended echo spacing reduces the number of echoes that can be formed and read out in an echo train of fixed temporal length. Thus, the minimum number of echo trains to be performed can increase, which also extends the measurement time required for the entire measurement. Alternatively, the temporal length of the echo trains and thus the repetition time TR would have to be extended and this, on the one hand, in turn increases the total measurement time and, on the other, due to the T1/T2 decay processes, also has a negative effect on the achievable image quality and the contrast achieved.

Dead times within a sequence also reduce the SNR efficiency of the sequence (SNR: signal-to-noise-ratio). The extended echo spacing also increases so-called T2 blurring, i.e., smearing of the image as a result of the T2 decay during the echo train.

The echo spacing extension is particularly serious for the above-described class of 3D TSE sequences, since the echo spacing extension for a conventional 2-point Dixon technique (for example with phase shifting of 0° and 180° between water and fat) is, for example, in the order of half an echo spacing (with a main magnetic field strength of 3 T) or a whole echo spacing (with a main magnetic field strength of 1.5 T). Due to this extension of the minimum echo spacing and the associated disadvantages, such as an increase in the number of echo trains required to record all measurement data and an extension of the total measurement time required, to date, 3D TSE techniques are therefore not necessarily compatible with clinical usage in conjunction with conventional Dixon techniques.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 a schematic flowchart of a method according to the disclosure.

FIG. 2 a schematically depicted part of a pulse sequence scheme for capturing according to the disclosure of measurement data with a first desired phase difference between two different spin species.

FIG. 3 a schematically depicted part of a pulse sequence scheme for capturing according to the disclosure of measurement data with a second desired phase difference between two different spin species.

FIG. 4 a schematic explanatory example of the formation of the above-described FID artifacts.

FIGS. 5-6 show examples of the generation of an advantageous phase-cycling scheme in pulse sequence schemes for capturing according to the disclosure measurement data with a first desired phase difference between two different spin species and for capturing according to the disclosure measurement data with a second desired phase difference between the different spin species.

FIGS. 7-8 show further examples of schematically depicted parts of pulse sequence schemes for capturing according to the disclosure measurement data with a desired phase difference between two different spin species.

FIG. 9 a schematic depiction of a magnetic resonance system according to the disclosure.

The exemplary embodiments of the present disclosure will be described with reference to the accompanying drawings. Elements, features and components that are identical, functionally identical and have the same effect are-insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

The disclosure is based on the object of using an MR sequence, in particular a TSE sequence, to record datasets with in each case different phase differences between signals of different spin species; this is to be done as free as possible of artifacts and quickly, in particular without extending a minimum echo spacing (for example, comparable with techniques without special phase positions of different spin species), or with a shortened minimum echo spacing compared to known TSE Dixon methods.

The object is achieved by a method for recording magnetic resonance data of an object under examination comprising spins of at least two different spin species, a magnetic resonance system, a computer program, and an electronically readable data carrier.

A method according to the disclosure for recording magnetic resonance data of an object under examination comprising spins of at least two different spin species may comprise:
irradiating a first RF excitation pulse and a sequence of at least two RF refocusing pulses such that a first echo train of at least two spin echo signals is formed, the spin echo signals of which are recorded and captured as measurement data in a first MR dataset, wherein the first RF excitation pulse generates a first desired phase difference between spins of a first spin species and spins of a second spin species of the at least two different spin species at the time at which the first spin echo signal of the first spin echo train is formed,
irradiating a second RF excitation pulse and a sequence of at least two RF refocusing pulses such that a second echo train of at least two spin echo signals is formed, the spin echo signals of which are recorded and captured as measurement data in a second MR dataset, wherein the second RF excitation pulse at the time at which the first spin echo signal of the second spin echo train is formed generates a second desired phase difference between spins of a first spin species and spins of a second spin species of the at least two different spin species, wherein the first desired phase difference and the second desired phase difference are different,
storing and/or further processing the first MR dataset and the second MR dataset, for example as part of a Dixon reconstruction.

Generating different desired phase differences between spins of a first spin species and spins of a second spin species according to the disclosure by irradiated RF excitation pulses in each case makes it possible to dispense with the above-described extension of echo spacings, which was previously necessary to generate different phase differences between the spin species. Thus, the method according to the disclosure enables the above-described disadvantages of the previously necessary extension of the echo spacing to be avoided. Instead, spin echo signals can be recorded both with the first desired phase difference and with the second desired phase difference symmetrically about the respective times of formation of the respective spin echo signals and captured as measurement data of the respective MR datasets. With the same resolution parameters and the same readout bandwidth for each pixel, the same minimum echo spacing of the first and of the second echo train can be achieved as with a conventional TSE sequence without changed phase differences between the spin species, i.e., as with a “non-CSI” or “non-Dixon” TSE sequence.

A magnetic resonance system according to the disclosure may comprise a magnet unit, a gradient unit, a radio-frequency unit and a control facility with a phase-shift unit for performing a method according to the disclosure.

A computer program according to the disclosure implements a method according to the disclosure on a control facility when it is executed on the control facility. For example, the computer may comprise program instructions which, when the program is executed by a control facility, for example a control facility of a magnetic resonance system, cause this control facility to execute a method according to the disclosure. The control facility can be in the form of a computer.

Herein, the computer program can also be provided in the form of a computer program product, which can be loaded directly into a memory of a control facility, with program code means for executing a method according to the disclosure when the computer program product is executed in a computing unit of the computing system.

A computer-readable storage medium according to the disclosure may comprise instructions which, when executed by a control facility, for example a control facility of a magnetic resonance system, cause the system to execute a method according to the disclosure.

The computer readable storage medium can be in the form of an electronically readable data carrier comprising electronically readable control information stored thereon, which may comprise at least one computer program according to the disclosure designed in such a way that, when the data carrier is used in a control facility of a magnetic resonance system, it performs a method according to the disclosure.

The advantages and embodiments disclosed in relation to the method also apply analogously to the magnetic resonance system, the computer program product and the electronically readable data carrier.

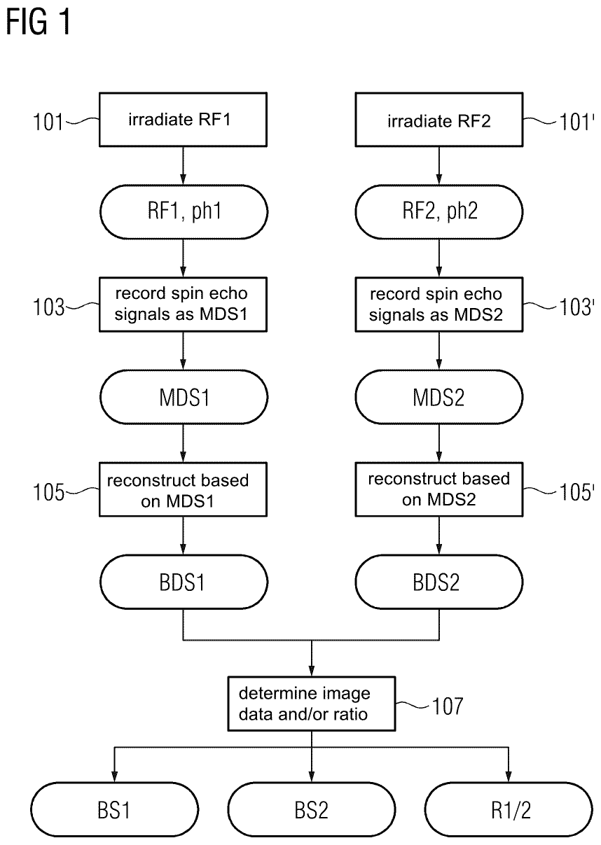

FIG. 1 is a schematic flowchart of a method according to the disclosure for recording magnetic resonance data of an object under examination comprising spins of at least two different spin species by means of a magnetic resonance system.

A first RF excitation pulse RF1 and a sequence of at least two RF refocusing pulses are irradiated (block 101) such that a first echo train of at least two spin echo signals is formed, wherein the first RF excitation pulse RF1 generates a first desired phase difference ph1 between spins of a first spin species and spins of a second spin species of the at least two different spin species at the time at which the first spin echo signal of the first spin echo train is formed.

The spin echo signals of the first echo train formed are recorded and captured as measurement data in a first MR dataset MDS1 (block 103).

A second RF excitation pulse RF2 and a sequence of at least two RF refocusing pulses are irradiated (block 101′) such that a second echo train of at least two spin echo signals is formed, wherein the second RF excitation pulse RF2 generates a second desired phase difference ph2 between spins of a first spin species and spins of a second spin species of the at least two different spin species at the time at which the first spin echo signal of the second spin echo train is formed.

The spin echo signals of the second echo train formed are recorded and captured as measurement data in a second MR dataset MDS2 (block 103′).

Spin echo signals can, for example, in each case be generated by means of a TSE sequence and captured or recorded as measurement data for the first MR dataset MDS1 and the second MR dataset MDS2.

The first MR dataset and the second MR dataset can be stored and/or further processed. For example, a first MR image dataset BDS1 can be reconstructed from the measurement data of the first MR dataset MDS1 (block 105). A second MR image dataset BDS2 can be reconstructed (block 105′) from the measurement data of the second MR dataset MDS2. At 107, image data of the first spin species BS1, image data of the second spin species BS2 and/or data on ratios of the first and second spin species to one another R½ can be determined, for example, in their spatial distribution, from the first and second MR image dataset BDS1 and BDS2, for example as part of a Dixon reconstruction.

The disclosure is based on the knowledge that RF pulses as described in the article by Arn et al., “A robust broadband fat-suppressing phaser T2 preparation module for cardiac magnetic resonance imaging at 3T”, Magn. Reson. Med.86: pp 1434-1444, 2021, used in a T2 preparation module in order to achieve fat saturation in addition to T2 preparation can be modified in such a way that they can be used as first and second RF excitation pulses according to the disclosure.

In the aforementioned article by Arn et al., the authors describe a T2 preparation module that (as usual) consists of a first RF excitation pulse, also referred to as a “tip down” RF pulse, which rotates the magnetization into the transverse plane, a number of RF refocusing pulses and a final RF pulse referred to as a “flip-back” RF pulse, which rotates the magnetization back into the longitudinal direction. Since the magnetization between the tip-down RF pulse and the flip-back RF pulse is subject to T2 decay, longitudinal magnetization after the T2 preparation module depends on the T2 decay constant of the tissue being examined. Transverse magnetization, which is generated by an RF excitation pulse of an imaging sequence following the T2 preparation module, is correspondingly T2-weighted.

In a usual T2 preparation module with two RF refocusing pulses, the phases of the RF refocusing pulses are typically rotated by 90° with respect to the phase of the tip-down RF pulse and the flip-back RF pulse, and a phase difference between the flip-back RF pulse and tip-down RF pulse is 180°. The authors replace the tip-down RF pulse of the T2 preparation module by a novel RF pulse that generates a specific phase Δφ between resonant spins (also called “on-resonance spins”), for example of water, and off-resonant spins (also called “off-resonance spins”), for example of fat, at the time of the flip-back RF pulse. The terminology off-resonance spins or on-resonance spins comes from the fact the resonance frequency of the on-resonance spins (often water) is usually used as the (“working”) frequency for the manipulation of the spins of an object under examination, and thus spin species with resonance frequencies different from the resonance frequency of these resonant spin species are also automatically off-resonant with respect to this working frequency.

The flip-back RF pulse then rotates the on-resonance spins into the longitudinal direction, whereas, due to their phase shifted by Δφ, the off-resonance spins remain in the transverse plane or already relaxed off-resonance spins are newly excited into the transverse plane where they are dephased by a spoiler gradient. In this way, the authors achieve simultaneous T2 preparation and fat suppression without the use of an additional frequency-selective RF fat saturation pulse.

The authors use simulation and phantom experiments to determine an optimal phase angle Δφ for fat suppression by which the phases of the off-resonance spins differ from the phase of the on-resonance spins, i.e., their phase difference. The result is a phase angle Δφ between 105° and 135° depending on the T2 preparation time (time between the tip-down and flip-back RF pulse of the T2 preparation module).

One idea of the present disclosure is to use an excitation pulse from the novel T2 preparation module in the aforementioned article by Arn et al. as an RF excitation pulse in a TSE sequence to generate a phase difference between different spin species, such as, for example, water and fat, such as required, for example, for a Dixon reconstruction.

Herein, according to the disclosure, the MR datasets with a different phase difference Δθ between two different spin species are recorded in different echo trains. Herein, the phase angle Δφ of a novel excitation pulse described in the article by Arn et al. can be set as equal to the desired phase difference ph1 or ph2 (“Δφ=ph1” or “Δφ=ph2”).

Since the desired phase difference ph1 or ph2 between spins of the first and the second spin species is induced by the respective RF excitation pulse RF1 or RF2, it is possible to dispense with a shift of the acquisition window by Δt away from the spin echo time and the associated extension of the echo spacing by 2Δt, as conventionally required. Instead, the spin echo signals are recorded as measurement data symmetrically about the spin echo time at the mid-point between two consecutive RF refocusing pulses, as in a conventional TSE sequence (without phase shifts).

In TSE techniques, account should be taken of special features of the signal formation that can restrict the technically possible phase shifts ph1, ph2. The following describes measures for determining first and second RF excitation pulses according to the disclosure, which also avoid dephasing of signals for TSE techniques.

It should be noted that, if the flip angle of RF refocusing pulses of a TSE sequence is less than 180°, each RF refocusing pulse affects both transverse and longitudinal magnetization. Longitudinal magnetization is partially excited into the transverse plane, partially inverted and partially unaffected. Transverse magnetization is partially refocused, partially flipped back into the longitudinal direction and partially left unaffected. Between RF refocusing pulses, transverse magnetization also accumulates phase as a result of inhomogeneities, for example of the main magnetic field B0 and/or the alternating magnetic field B1, and as a result of the gradients switched within the TSE sequence. Transverse magnetization that is flipped back into the longitudinal direction stores the previously accumulated phase. The interaction of the different RF refocusing pulses leads to a multitude of signal paths and echoes.

The so-called CPMG (Carr-Purcell-Meiboom-Gill) conditions formulate design guidelines for a TSE sequence that ensure that echo signals from magnetization following different signal paths are formed at the same time and that the phases of the echo signals superimpose coherently.

The CPMG conditions can be summarized as follows:

Condition 1: RF refocusing pulses must be shifted 90° out-of-phase with the phase of the preceding RF excitation pulse and must be evenly positioned in the sequence with equal spacing between two consecutive RF refocusing pulses. This spacing must be twice the time interval between the RF excitation pulse and the subsequent first RF refocusing pulse.

Condition 2: The phase accumulated by a spin species between two consecutive RF refocusing pulses must be the same.

If both condition 1 and condition 2 are fulfilled, primary echo signals and stimulated echo signals only occur at the mid-point between two consecutive RF refocusing pulses and carry the same phase.”

The following measures were determined inter alia from these CPMG conditions for determining the RF excitation pulses RF1 and RF2 and the respective sequence of at least two RF refocusing pulses of the first or second echo train:

When defining the phase relationship (condition 1) between a first or second RF excitation pulse RF1 or RF2 and a first RF refocusing pulse following this RF excitation pulse RF1 or RF2, the desired phase difference ph1 or ph2 to be generated by the respective RF excitation pulse RF1 or RF2 between spins of a first spin species and spins of a second spin species must also be considered. To ensure that condition 1 is reliably fulfilled both for off-resonant and for resonant spins, the phase difference ph1 or ph2 must be either 0° or 180°. Otherwise, it is not possible to rule out the possibility that the signal of the off-resonant spins dephases. A phase difference ph1=0° or ph2=0° corresponds to the in-phase condition and ph2=180° or ph1=180° of the opposed-phase condition of a conventional Dixon technique. This means that optimum phase differences ph1 and ph2 can be selected for a Dixon technique, in particular a 2-point Dixon technique.

As described in the aforementioned article by Arn et al., a first and/or second RF excitation pulse RF1, RF2 can be a superposition of two RF pulses B₁^{a}(t) and B₁^{b}(t), where:

$${B}_{1}^{a} ( t ) = \frac{A}{2} \{ \begin{matrix}SINC ( \frac{2 k π}{T} t ) ( {e}^{i \frac{Δ φ}{2}} {e}^{i \frac{2 k π}{T} t} ) & - \frac{T}{2} \leq t \leq \frac{T}{2} \\ 0 & else\end{matrix} \qquad ( 2 a )$$

$$and$$

$${B}_{1}^{b} ( t ) = \frac{A}{2} \{ \begin{matrix}SINC ( \frac{2 k π}{T} t ) ( {e}^{- i \frac{Δ φ}{2}} {e}^{- i \frac{2 k π}{T} t} ) & - \frac{T}{2} \leq t \leq \frac{T}{2} \\ 0 & else\end{matrix} , \qquad ( 2 b )$$

so that a first or second RF excitation pulse RFi (i=1 or i=2) can be written as:

$$RFi ( t ) = {B}_{I}^{a} ( t ) + {B}_{1}^{b} ( t ) = A \{ \begin{matrix}SINC ( \frac{2 k π}{T} t ) cos ( \frac{2 k π}{T} t + \frac{Δ φ}{2} ) , & - \frac{T}{2} \leq t \leq \frac{T}{2} \\ 0 & else\end{matrix} . \qquad ( 3 )$$

Herein, k is an integer that determines the bandwidth of the RF excitation pulse, T is the pulse duration and Δφ is the desired phase difference ph1 or ph2.

Thus, a first and/or a second RF excitation pulse RF1 or RF2 can be a sinc pulse, in particular a superposition of two sinc pulses.

Herein, the flip angle ∝, which is achieved by the respective RF excitation pulse RFi, is given by:

$$∝ = {\int }_{- \frac{T}{2}}^{\frac{T}{2}} γ RFi ( t ) dt \qquad ( 4 )$$

where γ is the gyromagnetic ratio, which for protons is

$$γ = 2 π 42 , 576 \frac{MHz}{T} .$$

One difficulty arises from the fact that the amplitude integral of such an RF excitation pulse RFi is zero for Δφ=180° zero. This problem was solved by calculating the amplitude integral of the individual pulses B₁^{a}(t) and B₁^{b}(t) in order to determine a maximum amplitude A of a such an RF excitation pulse RFi from the desired flip angle ∝.

For example, in order to maintain a maximum amplitude of an RF excitation pulse RFi for an excitation of water and fat spins as spins of the different spin species with a usual RF bandwidth BW=4k/T and with a desired flip angle α within the specifications of a usual RF power amplifier, a relatively long pulse duration (in the order of several milliseconds) is required. For example, for k=3, pulse duration T=8000 μs and flip angle α=90°, a bandwidth of BW=4k/T=12/(0.008 sec)=1500 Hz results, for example, in a maximum amplitude A=9.11 μT for a first or second RF excitation pulse RFi.

For ph1=0° and ph2=180° or ph1=180° and ph2=0°, isodelay points of such a first or second RF excitation pulse RF1 or RF2 in each case lie in the temporal mid-point of the RF excitation pulse. Herein, the isodelay point of an RF pulse is the time during the irradiation of the RF pulse relative to which a spin echo is formed in interaction with an RF refocusing pulse.

A typical echo spacing of known 3D TSE techniques is in the order of a few milliseconds, for example 4 ms. According to CPMG condition 1, the time interval between the RF excitation and first subsequent RF refocusing pulse is equal to half the echo spacing, i.e., 2 ms in the example given.

In order to fulfill CPMG condition 1, it appears necessary to either select a short duration of the first and/or second RF excitation pulse RFi or to extend the echo spacing in the entire sequence used accordingly. Shortening the duration of an RF excitation pulse RFi can prove difficult since a maximum amplitude of the first or second RF excitation pulse RFi must still be kept within the specification of the RF power amplifier used. An extension of the echo spacing is not really desirable due to the above-described disadvantages.

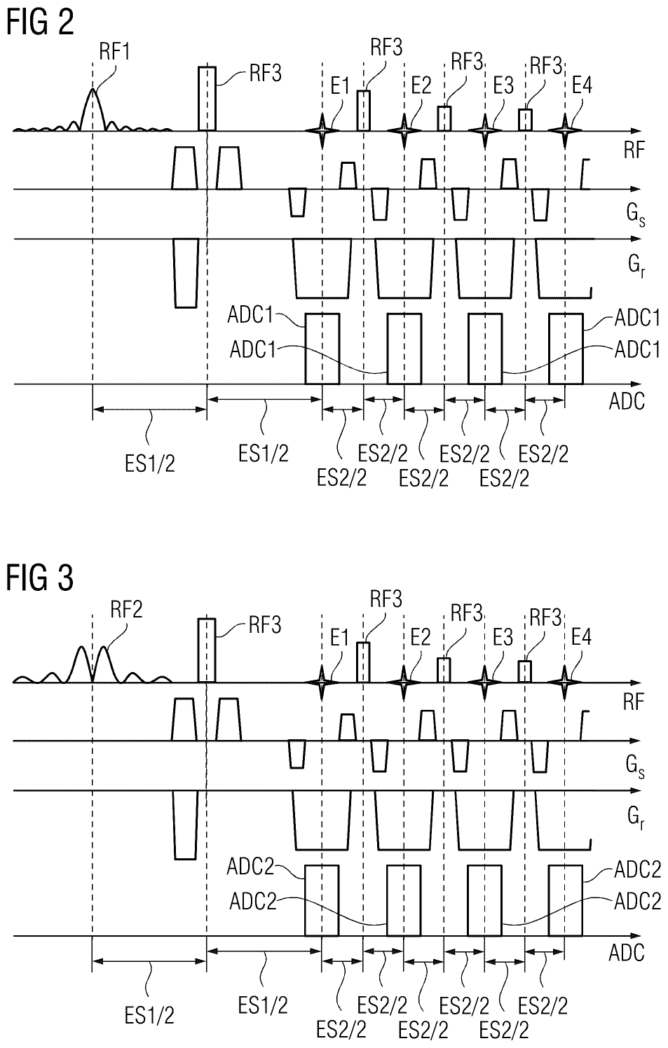

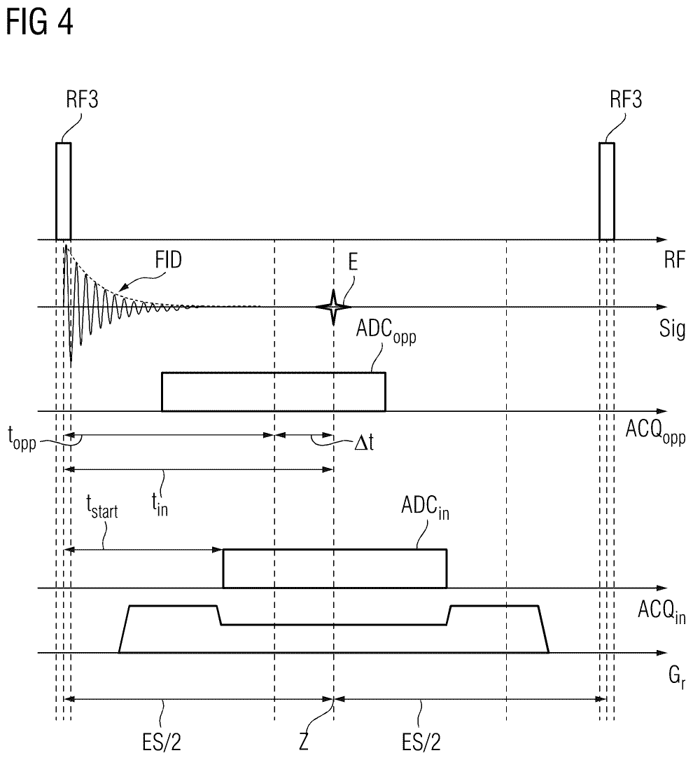

FIGS. 2 and 3 are in each case a schematic depiction of part of a pulse sequence scheme for capturing according to the disclosure measurement data with a desired phase difference between two different spin species, wherein in FIG. 2 a first desired phase difference is generated by a first RF excitation pulse RF1 and in FIG. 3 a second desired phase difference is generated by a second RF excitation pulse RF2, which is why the pulse sequence schemes shown in FIGS. 2 and 3 are the same except for the RF excitation pulses RF1 and RF2. The uppermost line RF in each case shows irradiated RF pulses RF1, RF2, RF3 and generated spin echo signals E1, E2, E3, E4, . . . in their temporal course and in relation to gradients to be switched in the slice-selection direction depicted in the second line Gₛ and to gradients to be switched in the readout direction depicted in the third line Gᵣ and in relation to acquisition windows ADC1, ADC2 depicted in the bottommost line ADC. A temporal course of the sequence of at least two RF refocusing pulses RF3 after a first RF excitation pulse RF1 can therefore in particular be selected as the same as the temporal course of the sequence of at least two RF refocusing pulses RF3 after the second RF excitation pulse RF2.

The first RF excitation pulse RF1 in FIG. 2 generates, for example, a first phase difference of 0° between spins of two different spin species contained in an object under examination, for example water and fat, and, together with the subsequent sequence of RF refocusing pulses RF 3, generates a first echo train E1, E2, E3, E4, . . . . The number of spin echo signals E1, E2, E3, E4, . . . generated in a first echo train can be selected in dependence on the echo train length, the repetition time TR and the echo spacings ES1, ES2 used.

The second RF excitation pulse RF2 in FIG. 2 generates, for example, a second phase difference of 180° between spins of two different spin species contained in an object under examination, for example water and fat, and, together with the subsequent sequence of RF refocusing pulses RF 3, generates a second echo train E1, E2, E3, E4, . . . . Like the first echo train, the number of spin echo signals E1, E2, E3, E4 generated in a second echo train can be selected in dependence on the echo train length, the repetition time TR and the echo spacings ES1, ES2 used.

Thus, spin echo signals E1, E2, E3, E4, . . . of the first echo train can be recorded in first acquisition windows ADC1 and captured as measurement data of the first MR dataset MDS1 and spin echo signals E1, E2, E3, E4, . . . of the second echo train can be recorded in second acquisition windows ADC2 and captured as measurement data of the second MR dataset MDS2, wherein first and second acquisition windows ADC1, ADC2 can have the same duration and the same temporal arrangement relative to the respective RF refocusing pulses.

Echo times at which the first spin echo signal E1 of the first and the second echo train are formed can be generated after the same time interval after the respective preceding RF excitation pulse RF1 or RF2 and can in each case be recorded centrally by a corresponding acquisition window ADC1 or ADC2. Thus, spin echo signals E1, E2, E3, E4, . . . of the first echo train can be recorded with the same minimum echo spacing ES1 after the respective RF excitation pulse RF1 or RF2; in particular, there is no need to shift the acquisition windows ADC2 relative to the acquisition windows ADC1.

As FIGS. 2 and 3 show, it is possible to select the first echo spacing ES1 between the RF excitation pulse RF1 or RF2 and the first spin echo signal E1 of the respective echo train as longer than the second (later) echo spacings ES2 between spin echo signals E2, E3, E4, . . . following the first spin echo signal E1 and the preceding spin echo signal E1, E2, E3 in each case, without all echo spacings ES1, ES2 of the respective echo train having to be extended. Thus, a time interval between an irradiated RF excitation pulse RF1 or RF2 and a first spin echo signal El of the corresponding echo train formed after the RF excitation pulse RF1 or RF2 can be greater than time intervals between later spin echo signals of the respective echo train.

The first spin echo signal E1 of the respective echo train is, for example, repeatedly refocused by a sequence of non-selective RF refocusing pulses RF3 with a second echo spacing ES2 that is shorter than the first echo spacing ES1. The time interval between the first spin echo signal E1 and the following second RF refocusing pulse RF3 of the sequence of at least two RF refocusing pulses is

$$\frac{ES 2}{2}$$

. Again, a second spin echo signal E2 of the echo train is formed a time interval

$$\frac{ES 2}{2}$$

after the second RF refocusing pulse RF3, and so on.

In general, at least one of the RF refocusing pulses RF3 of a sequence of at least two RF refocusing pulses RF3 can be a short non-selective RF refocusing pulse RF3 with a flip angle of less than 180°, in particular an RF refocusing pulse according to a SPACE technique.

Stimulated echoes associated with the first RF refocusing pulse RF3 of the sequence of at least two RF refocusing pulses would be formed at a different undesirable time. For example, a stimulated echo formed by the respective RF excitation pulse RF1, RF2, the first and the second RF refocusing pulse of the sequence of at least two RF refocusing pulses would have a time interval corresponding to the sum of half the first echo spacing ES1 and half the second echo spacing ES2

$$( \frac{{ES}_{1}}{2} + \frac{{ES}_{2}}{2} )$$

after the first spin echo signal E1, i.e., later than the second spin echo signal E2 generated by the three RF pulses mentioned, which is formed after the second echo spacing ES2 after the first spin echo signal E1. In order to avoid the formation of such undesirable stimulated echo signals in which the first RF refocusing pulse RF3 of the sequence of least two RF refocusing pulses is involved, the flip angle of the first RF refocusing pulse RF3 of the sequence of at least two RF refocusing pulses can be set as equal to 180°. Although, due to a technically unavoidable variation of the B1 field in the captured volume, this cannot completely avoid undesirable stimulated echo signals, these can, for example, be dephased by so-called crusher gradients (also referred to as spoiler gradients), which are switched before and after the first RF refocusing pulse RF3 of the sequence of at least two RF refocusing pulses. Such crusher gradients switched around the first RF refocusing pulse RF3 of the sequence of at least two RF refocusing pulses can prevent undesirable stimulated echo signals, since the magnetization that would later form the stimulated echo is only located between the excitation by the RF excitation pulse RF1 or RF2 and the first RF refocusing pulse RF3 of the sequence of at least two RF refocusing pulses in the transverse plane and is thus only affected by the crusher gradient that is switched before the first RF refocusing pulse RF3. Thus, there is no rephasing of the signal by the second crusher gradient, which is switched after the first RF refocusing pulse RF3.

On the other hand, the magnetization that later forms the first spin echo E1 is located both between the RF excitation pulse RF1 or RF2 and the first RF refocusing pulse RF3 and after the first RF refocusing pulse RF3 in the transverse plane and is thus dephased by the first crusher gradient, which is switched before the first RF refocusing pulse RF3 and rephased by the second crusher gradient, which is switched after the first RF refocusing pulse RF3. A similar sequence design with an extended first echo spacing is, for example, used in the aforementioned article by Mugler for a sliced-selective variant of the SPACE sequence. In this, a relatively long selective RF excitation pulse is switched together with a slice-selection gradient in order to limit the excitation volume in the direction of the gradient.

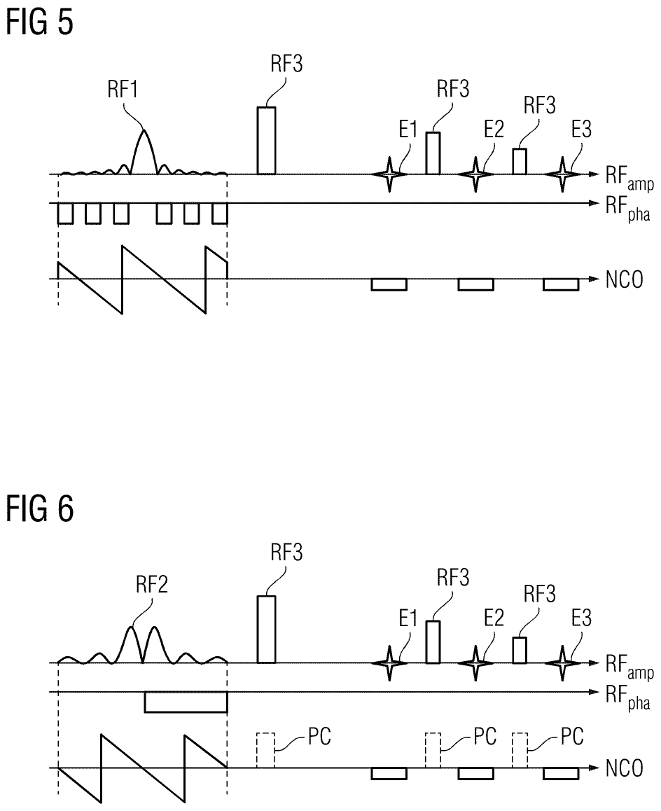

FIG. 4 is a schematic explanatory example of the formation of the aforementioned FID artifacts, which are, for example, formed when longitudinal magnetization, which has, for example, arisen due to T1 relaxation since the excitation of magnetization, is excited again into the transverse plane by an RF refocusing pulse RF3. Therefore, the total duration of an echo train in relation to the T1 decay constant of the tissue to be examined is also relevant for the influence on FID signals. The longer the duration of the echo trains used, the more undesirable FID artifacts appear. Therefore, FID artifacts are particularly problematic with known 3D TSE techniques. Furthermore, the more longitudinal magnetization is excited instead of inverted by the RF refocusing pulses used, the more FID artifacts appear. Therefore, if RF refocusing pulses with a significant deviation of the flip angle of 180° are used, a relatively large proportion of the longitudinal magnetization is excited thereby, so that measures, such as the aforementioned phase cycling, should be used to remedy the undesirable FID artifacts.

In FIG. 4, the uppermost line RF depicts two consecutive RF refocusing pulses RF3, which are, for example, spatially non-selective and in each case have a flip angle of <180°. The second line Sig depicts resulting signals; in the present case, an FID signal FID after the first RF refocusing pulse RF3 shown and an echo signal E that is generated at time Z, i.e., half an echo spacing ES/2 after the first RF refocusing pulse RF3 shown and a further half echo spacing ES/2 before the second RF refocusing pulse RF3 shown. In the third line ACQₒₚₚ and the fourth line ACQᵢₙ a known typical acquisition window for recording measurement data for an MR dataset with an opposed-phase condition ADCₒₚₚ and a typical acquisition window for recording measurement data for an MR dataset with an in-phase condition ADCᵢₙ are contrasted. The fifth line depicts by way of example gradients to be switched in the readout direction G_{R} when recording measurement data for an MR dataset with an in-phase condition.

As can be seen in FIG. 4, the time tₒₚₚ that elapses after the excitation of the FID signal FID until the acquisition window for recording measurement data for an MR dataset with a opposed-phase condition ADCₒₚₚ scans the k-space center is shorter by the time interval Δt than the time tᵢₙ that elapses after the excitation of the FID signal FID until the acquisition window for recording measurement data for an MR dataset with an in-phase condition ADCᵢₙ scans the k-space center. Accordingly, the time tₛₜₐᵣₜ that elapses after the excitation of the FID signal FID until the acquisition window for recording measurement data for an MR dataset with an in-phase condition ADCᵢₙ starts is longer by the time interval Δt than the time (not shown separately) that elapses after the excitation of the FID signal FID until the acquisition window for recording measurement data for an MR dataset with an opposed-phase condition ADCₒₚₚ starts. Thus, due to the off-resonance and the shift by the time interval Δt, spins of an off-resonant spin species (for example fat) that are recorded as measurement data with an acquisition window ADCₒₚₚ accumulate a different phase than spins of the off-resonant spin species that are recorded with an acquisition window ADCᵢₙ. Therefore, FID signals originating from a resonant spin species (for example water or free protons) can be separated from FID signals originating from an off-resonant spin species as part of a Dixon reconstruction.

This is not the case for recordings according to the disclosure of at least one MR dataset corresponding to an opposed-phase condition and at least one MR dataset corresponding to an in-phase condition, MDS1, MDS2, which are furthermore in each case recorded within an acquisition window with a mid-point coinciding with the time Z of formation of a spin echo signal and thus in each case correspond to an acquisition window ADCᵢₙ in FIG. 4. Recordings according to the disclosure of at least one MR dataset corresponding to an opposed-phase condition and at least one MR dataset corresponding to an in-phase condition, MDS1, MDS2, generally only differ in their respective RF excitation pulse RF1, RF2.

Since the respective RF excitation pulse RF1, RF2 is not involved in the generation of an FID signal FID after an RF refocusing pulse RF3, it also has no influence on the phase of the acquired FID signal. Instead, the FID signal acquires phase as a result of off-resonances in the time interval between excitation by the RF refocusing pulse RF3 and its acquisition in the acquisition window ADCᵢₙ and as a result of the gradients switched in this time interval. Thus, the FID signal that is excited by a specific RF refocusing pulse has the same phase in the measurement dataset MDS1 and MDS2. Accordingly, a conventional Dixon reconstruction assigns any FID signal FID to the image dataset of the resonant spin species, for example the water image, regardless of whether the FID signal FID originates from protons belonging to the resonant spin species or the off-resonant spin species.

However, generally, the water image is more important for diagnosis, so that FID artifacts are perceived as disruptive. In an advantageous embodiment of the disclosure, artifacts caused by FID signals can be assigned to the image dataset of the off-resonant spin species by a phase-cycling scheme.

For this purpose, a first phase of RF refocusing pulses RF3 of a sequence of RF refocusing pulses RF3 after a first RF excitation pulse RF1, which generates a first desired phase difference ph1 between spins of a first spin species and spins of a second spin species, can be selected such that this (first phase) differs from a second phase of RF refocusing pulses RF3 of a sequence of RF refocusing pulses RF3 after a second RF excitation pulse RF2, which generates a second desired phase difference ph2 between spins of the first spin species and spins of the second spin species by exactly the difference of the two phase differences ph1 and ph2 (i.e., (ph1−ph2)), or, for a difference in phase differences of 180°, by the amount of the difference between the two phase differences ph2 and ph1 (i.e., |ph2−ph1|). The phases of the RF excitation pulses RF1 or RF2 can then in turn be adapted to the respective (first or second) phase of the respective RF refocusing pulses RF3 in such a way that the CPMG condition 1 is (further) fulfilled.

Thus, the phase of an RF refocusing pulse RF3 in a sequence of at least two RF refocusing pulses RF3 after a second RF excitation pulse RF2 can differ from the phase of the corresponding RF refocusing pulse RF3 of a sequence of at least two RF refocusing pulses RF3 after a first RF excitation pulse RF1 by the difference between the first desired phase difference and the second desired phase difference. Since the relative phase between the FID signals in the two datasets MDS1 and MDS2 now corresponds exactly to the phase difference expected for the second off-resonant spin species (for example fat), a Dixon reconstruction assigns any FID signal to the image dataset of the off-resonant spin species (i.e., in the example, the fat image), regardless of whether the FID signal originates from protons belonging to the resonant spin species or the off-resonant spin species. In particular, the phases of corresponding RF refocusing pulses RF3 of the sequence of at least two RF refocusing pulses RF3 after a first RF excitation pulse RF1 and the sequence of at least two RF refocusing pulses RF3 after a second RF excitation pulse RF2 can have a phase difference of 180°, whereby optimum phase differences ph1 and ph2 of the different spin species are used, in particular for a 2-point Dixon technique.

Accordingly, the phases of corresponding FID signals in a corresponding first or a corresponding second echo train, and likewise their associated RF refocusing pulses RF3, will differ by the difference of the phase differences ph1 and ph2, resulting in a type of phase-cycling scheme. The phases of the spin echo signals E1, E2, E3, E4, . . . are unaffected by the phase-cycling scheme, since the relative phase between the RF excitation pulse RF1 or RF2 and the subsequent RF refocusing pulse RF3 is unchanged. It is thus possible that the recording of the spin echo signals E1, E2, E3, E4, . . . , which are captured as measurement data in the first and second MR dataset MDS1 and MDS2, may comprise a phase-cycling method, whereby FID artifacts in the image dataset of the on-resonant spin species can be suppressed. Such a phase-cycling scheme for shifting FID artifacts into the image dataset of the off-resonant spin species is unique and would have a different effect in a conventional TSE Dixon sequence without the RF excitation pulses RF1 and RF2 according to the disclosure, which each generate a desired phase difference between different spin species.

With such a phase-cycling scheme, the relative phase between the FID signals in the two MR datasets MDS1 and MDS2 now corresponds exactly to the phase difference expected for the off-resonant spin species (for example, fat). Therefore, a Dixon reconstruction will now assign all FID signals to the image dataset of the off-resonant spin species (for example, the fat image), and, to be precise, regardless of whether the FID signals originate from the first or the second spin species, i.e., for example whether the FID signals originate from tissue consisting of fat or water.

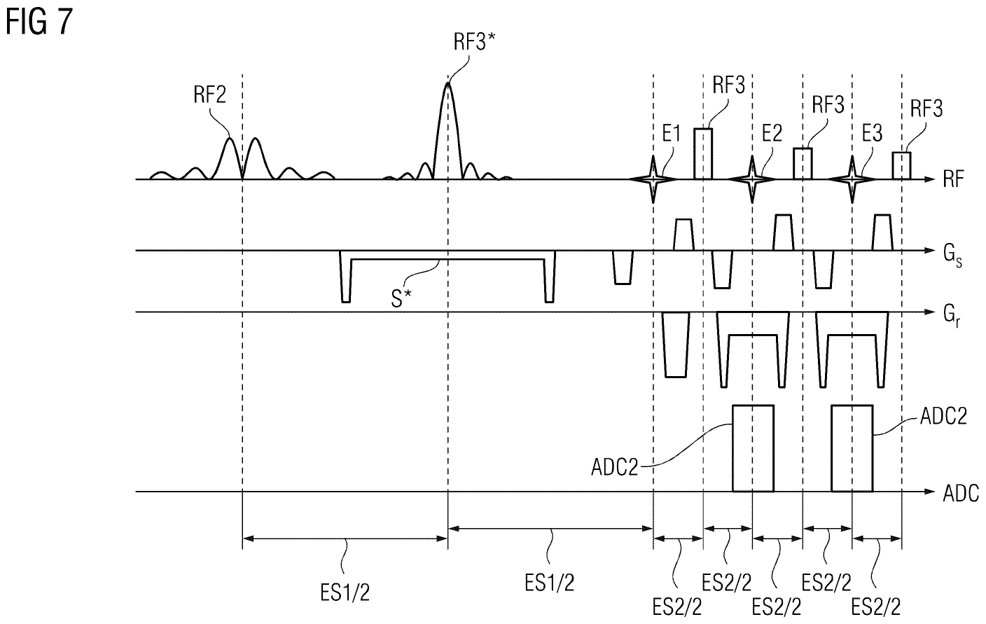

FIGS. 5 and 6 are schematic depictions of an example of such a phase-cycling scheme in pulse sequence schemes for capturing according to the disclosure of measurement data with a first desired phase difference between two different spin species on the one hand and capturing according to the disclosure measurement data with a second desired phase difference between the different spin species on the other.

For example, for a two-point Dixon technique, after a first RF excitation pulse RF1, a first MR dataset MDS1 with a first desired phase difference ph1 between different spin species, such as, for example, already described with reference to FIG. 2, and after a second RF excitation pulse RF2, a second MR dataset MDS2 with a second desired phase difference ph2 between the different spin species, such as, for example, already described with reference to FIG. 3, can be captured.

The line RFamp depicted in each case in FIG. 5 or FIG. 6 shows the temporal course of the (envelope of the) amplitude of the RF pulses RF1, RF2, RF3 to be irradiated, and can, for example, in each case correspond to the uppermost line RF in FIG. 2 or FIG. 3. In FIGS. 5 and 6, in each case a second line RFpha additionally depicts corresponding phases of the RF pulses RF1, RF2, RF3 to be switched and a bottommost line NCO depicts the corresponding phase of the numerically controlled oscillator (NCO).

Thus, an advantageous phase-cycling method can comprise generating a different phase of RF refocusing pulses RF3 of the sequence of at least two RF refocusing pulses after a first RF excitation pulse RF1 on the one hand and the sequence of at least two RF refocusing pulses RF3 after a second RF excitation pulse RF2 on the other by means of an NCO.

In one example, an RF excitation pulse RF1 from FIG. 5 generates a first phase difference ph1 of different spin species, which corresponds to an in-phase condition) (ph1=0°) and an RF excitation pulse RF2 from FIG. 6 generates a second phase difference ph2 of the different spin species, which corresponds to an opposed-phase condition (ph2=180°).

The phase of the RF refocusing pulses RF3 for generating a first echo train E1, E2, E3 after an RF excitation pulse RF1 (FIG. 5), can, for example, be set as equal 0° and the phase of the RF refocusing pulses RF3 for generating a second echo train E1, E2, E3 after an RF excitation pulse RF2 (FIG. 6) can accordingly be set as equal to 180°. Thus, the phases of the RF refocusing pulses RF3 of the first and second echo trains differ by ph2−ph1=180°. According to the CPMG condition 1, the phase of the RF excitation pulses RF1 and RF2 can now accordingly, for example, be set as equal to 90° for both echo trains.

In order to set the initial phase of the RF excitation pulses RF1 and RF2 accordingly, the phase of an NCO used at the start and end of the respective RF excitation pulse RF1 or RF2 can be defined as follows:

The following should apply at the start of the respective RF excitation pulse RF1 or RF2:

$${θ}_{NCO} ( t = - \frac{T}{2} ) = - 360 ° * \frac{T}{2} * {f}_{0} - \frac{Δφ}{2} + {α}_{0} \qquad ( 5 a )$$

The following should apply at the end of the respective RF excitation pulse RF1 or RF2:

$${θ}_{NCO} ( t = + \frac{T}{2} ) = - 360 ° * \frac{T}{2} * {f}_{0} + \frac{Δφ}{2} - {α}_{0} . \qquad ( 5 b )$$

Herein, T is the pulse duration, Δφ is the respective desired phase difference between the different spin species, f₀ is the off-resonance frequency of the respective RF excitation pulse RF1 or RF2, which is typically set between the resonance frequency of the resonant spin species (0 Hz) and the resonance frequency of the off-resonant spin species (for example −210/−420 Hz at 1.5 T/3 T field strength for protons bound to fat molecules), and α₀ is the desired phase of the excitation pulse. Therefore, in the example, α₀=90° is set. The further pulse parameters of RF excitation pulses can, for example, be T=10000 μs for the pulse duration and f₀=−200 Hz for the off-resonance frequency (at a main field strength of 3 T) or f₀=−100 Hz (at a main field strength of 1.5 T).

With these examples of parameters, formulas 5a and 5b produce an NCO phase at the start and end of the RF excitation pulse RF1 (with) ph1=0°) of +90° in each case, and an NCO phase at the start and end of the RF excitation pulse RF2 (with ph2=180°) of 0° in each case, as depicted in FIGS. 5 and 6. In order to fulfill the phase-cycling scheme described herein, it is furthermore necessary for a phase of the RF refocusing pulses RF3, which are irradiated after one of the RF excitation pulses RF1 or RF2, as described above, to differ by a phase difference ph2−ph1 (for example, for the special case of ph1=0° and ph2=180°, a phase difference of 180°) from the phase of the RF refocusing pulses RF3, which are irradiated after the other RF excitation pulse RF2 or RF1. For this purpose, as depicted in FIG. 6, for example, a phase PC of 180° can be generated by means of the NCO for all RF refocusing pulses RF3 after the RF excitation pulse RF2.

Although the phase-cycling scheme is not realized without the imposition of the phase difference PC of ph2−ph1 between the RF refocusing pulses RF3 of the different echo trains of the two MR datasets MDS1 and MDS2, it is still possible to record the measurement data for the MR datasets MDS1 and MDS2 without the imposition of phases PC.

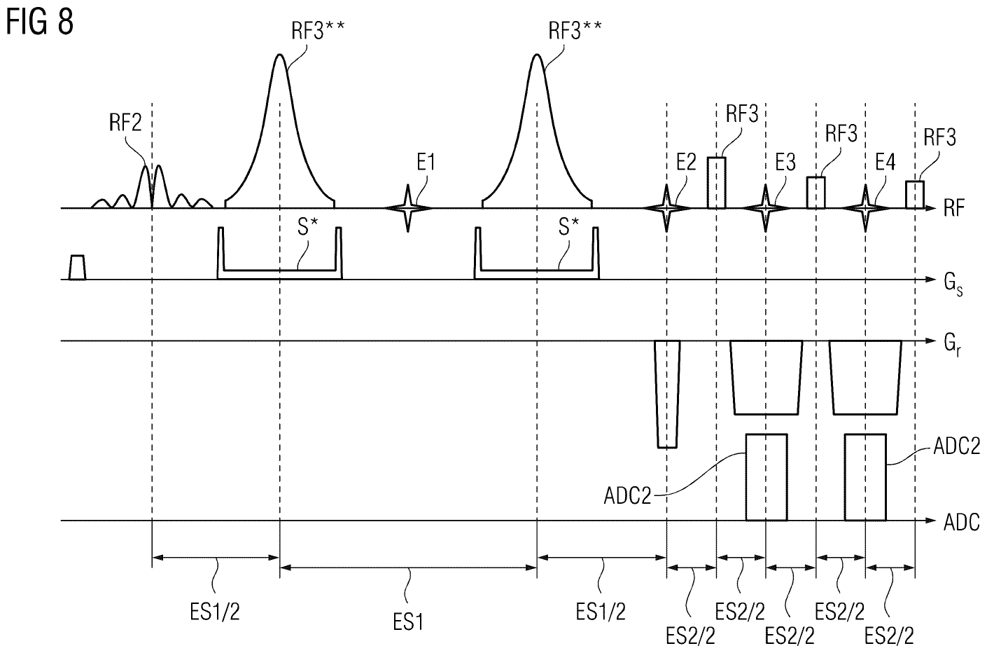

FIG. 7 shows a further example of a schematically depicted part of a pulse sequence scheme for capturing according to the disclosure measurement data with a desired phase difference between two different spin species. As in FIGS. 2 and 3, the uppermost line RF in FIG. 7 shows irradiated RF pulses RF2, RF3 and generated spin echo signals E1, E2, E3 . . . in each case in their temporal course and in relation to gradients to be switched in the slice-selection direction depicted in the second line Gₛ and to gradients to be switched in the readout direction depicted in the third line Gᵣ and in relation to acquisition windows ADC2 depicted in the bottommost line ADC. Like FIG. 3, FIG. 7 shows a second RF excitation pulse RF2 and second acquisition window ADC2 for recording measurement data of a second MR dataset MDS2 with a second phase difference ph2 between spins of different spin species. Recording of measurement data of a first MR dataset MDS1 with a first phase difference ph1 between spins of the different spin species by RF excitation pulses RF1 and acquisition windows ADC1 can take place analogously.

In contrast to FIG. 3, the first RF refocusing pulse RF3* of the sequence of at least two RF refocusing pulses RF3 after the RF excitation pulse RF2 is slice-selective, whereby spins are only refocused in the slice selected by this first RF refocusing pulse RF3* and the gradients S* and can contribute in later spin echo signals. Thus, the entire recording of measurement data for the second MR dataset MDS2 becomes slice-selective.

For this purpose, during the irradiation of the first RF refocusing pulse RF3* of the sequence of at least two RF refocusing pulses RF3 after the RF excitation pulse RF2, which can, for example, be executed with limited bandwidth, a gradient S* which defines the layer to be selected with the simultaneously irradiated RF refocusing pulse RF3* can be switched in the slice-selection direction. As a result, only spins in a limited volume are refocused in the direction of the simultaneously switched gradients S* and can contribute to the first spin echo signal E1.

As explained with reference to FIGS. 2 and 3, stimulated echo signals, in the formation of which the first and here slice-selective RF refocusing pulse RF3* is involved, can be avoided or suppressed in order to prevent them from destructively interfering with desired spin echo signals E1, E2, E3, . . . of the echo train. For this purpose, as also already described with reference to FIGS. 2 and 3, the flip angle of the first, here slice-selective, RF refocusing pulse RF3* can be selected as close as possible to 180°. Furthermore, crusher gradients, which can, for example, be switched before and after the gradient S*, can be used to dephase the signals of stimulated echoes (and also FIDs) in which the first, here slice-selective RF, refocusing pulse RF3* is involved. As a result, inhomogeneities, for example of the main magnetic field B0 and/or the alternating magnetic field B1, which can make it difficult to realize a flip angle close to 180°, in particular in the edge regions of a desired slice, are less important.

It is often difficult to realize a homogeneous B1 field over the entire volume to be mapped, in particular if, for example, local coils are also used as transmission coils.

Any signal originally excited into the transverse plane by the RF excitation pulse RF2 that is not refocused by the first, here slice-selective, RF refocusing pulse RF3* does not contribute to the desired echo signals E1, E2, E3, . . . and is therefore “lost”.

This disadvantage can be avoided by the use of adiabatic RF pulses as first RF refocusing pulses RF3 of the sequence of at least two RF refocusing pulses RF3.

Adiabatic RF pulses are a special class of RF pulses that can realize a constant flip angle over the entire imaging volume, even with a spatially varying B1 field, provided that their B1 amplitude exceeds a specific threshold value (the so-called adiabatic limit).

For example, in each case a first slice-selective RF refocusing pulse RF3* in FIG. 7 can be an adiabatic slice-selective RF refocusing pulse RF3*.

Such adiabatic slice-selective RF refocusing pulses are conventionally known, but have the disadvantage that they are sensitive to off-resonances.

A distinction is made between adiabatic RF inversion pulses and adiabatic RF refocusing pulses. An adiabatic RF inversion pulse has the task of tilting longitudinal magnetization from the +z-axis (i.e., aligned with the static B0 field) into the −z-axis (i.e., directed against the B0 field). An adiabatic RF refocusing pulse rotates transverse (or longitudinal) magnetization by 180° about an axis in the transverse plane. An adiabatic RF refocusing pulse is characterized by the fact that it rotates all spins um 180° regardless of their phase position in the transverse plane (i.e., even if the magnetization has already dephased since the excitation), so that an echo signal is formed at a later time. On the other hand, if an adiabatic RF inversion pulse is used for refocusing, the magnetization dephases during the adiabatic RF inversion pulse. This results in an extra phase at the time of the echo, which would violate the CPMG condition.

However, it is also possible to use two identical adiabatic RF inversion pulses for refocusing since the second inversion pulse then completely compensates the phase dispersion generated by the first inversion pulse.

One example of such a pulse sequence scheme is shown in FIG. 8. As in FIGS. 2, 3 and 7, in FIG. 8, the uppermost line RF shows irradiated RF pulses RF2, RF3 and generated spin echo signals E1, E2, E3, E4, . . . in each case in their temporal course and in relation to gradients to be switched in the slice-selection direction depicted in the second line Gₛ and to gradients to be switched in the readout direction depicted in the third line Gᵣ and in relation to acquisition windows ADC2 depicted in the bottommost line ADC. Like FIG. 3 or FIG. 7, FIG. 8 shows a second RF excitation pulse RF2 and second acquisition windows ADC2 for recording measurement data of a second MR dataset MDS2 with a second phase difference ph2 between spins of different spin species. Recording of measurement data of a first MR dataset MDS1 with a first phase difference ph1 between spins of the different spin species by RF excitation pulses RF1 and acquisition windows ADC1 can take place analogously.

In FIG. 8, the first and the second RF refocusing pulses RF3** of the sequence of at least two RF refocusing pulses after the RF excitation pulse RF2 are shown as adiabatic RF inversion pulses, which refocus magnetization rotated into the transverse plane by the RF excitation pulse RF2 twice in order to form a spin echo signal E2 half a first echo spacing ES1/2 after the second adiabatic RF inversion pulse RF3**.

Here, the first echo spacing ES1 is equal to the time interval of the two adiabatic RF inversion pulses RF3**. The time interval between the RF excitation pulse RF2 and the first inversion pulse RF3** is likewise ES1/2.

Thus, both a time interval between an irradiated RF excitation pulse and a first spin echo signal E1 of the corresponding echo train formed after the RF excitation pulse and a time interval between a first and a second spin echo signal E1 and E2 formed after the RF excitation pulse can be greater than time intervals between later spin echo signals E2, E3, E4, . . . of the echo train.

A spin echo signal E2 formed by the RF excitation pulse RF2 and the two RF inversion pulses RF3** can be refocused again multiple times by short non-selective further RF refocusing pulses RF3 in order to form further spin echo signals E3, E4, . . . . The use of short non-selective RF refocusing pulses RF3 allows the second echo spacing ES2 to be again selected as significantly shorter than the first echo spacing ES1, thereby retaining the above-described advantages.

In order to make the two first RF refocusing pulses RF3**, and thus the recording of the measurement data for the second MR dataset MDS2, slice-selective, gradients S* can be switched in the slice-selection direction, analogously to the example described with reference to FIG. 7, when the RF refocusing pulses RF3** are irradiated. Furthermore, analogously to the example described with reference to FIG. 7, crusher gradients can advantageously be switched before and after the gradients S* at least in the slice-selection direction.

Therefore, a first RF refocusing pulse RF3*, RF3** and/or a second RF refocusing pulse RF3** of a sequence of at least two RF refocusing pulses after a switched (first or second) RF excitation pulse RF1 or RF2 can be slice-selective. In particular, if both the first and the second RF refocusing pulse RF3** of the sequence of at least two RF refocusing pulses are slice-selective, the same gradient S*, i.e., a gradient of the same strength, can in each case be switched in the slice-selection direction with the first and the second RF refocusing pulse RF3** of the sequence of at least two RF refocusing pulses.

A first RF refocusing pulse RF3, RF3*, RF3** of a sequence of at least two RF refocusing pulses can generate a flip angle of 180° in order to avoid undesirable stimulated echo signals.

As explained above, a first RF refocusing pulse and/or a second RF refocusing pulse of a sequence of at least two RF refocusing pulses after an irradiated RF excitation pulse RF1 or RF2 can be embodied as an adiabatic RF pulse, in particular an adiabatic RF inversion pulse or an adiabatic RF refocusing pulse. This can reduce sensitivity to inhomogeneities in the B1 field.

A method presented herein for recording magnetic resonance data of an object under examination comprising spins of at least two different spin species allows MR datasets with different phase differences between spins of different spin species to be recorded without having to adapt an echo spacing, apart from first and/or second echo spacing, as explained in connection with FIGS. 2, 3, 7 and 8. This enables, for example, input images for a Dixon reconstruction to be recorded in separate echo trains. Two separate MR datasets MDS1 and MDS2 are recorded. Even with conventional (non-CSI-) TSE methods, a plurality of (at least two) MR datasets are often recorded, either to increase an SNR or to be able to perform a phase-cycling method, so that the total measurement time required is comparable.

The MR datasets recorded according to the disclosure can be used to perform a Dixon reconstruction so that, for example, an undesirable fat signal can be eliminated, with or without reduced sensitivity to inhomogeneities of the B0 field, compared to other fat saturation methods with frequency-selective prepulses.

According to the disclosure, different desired phase differences between spins of a first spin species and spins of a second spin species are generated by irradiated RF excitation pulses in each case and corresponding MR datasets are recorded in respective echo trains after irradiation of the RF excitation pulses. This makes it possible to dispense with a shift in the readout interval away from the spin-echo time and the associated extension of echo spacings that was previously necessary to generate the different phase differences in order to generate the different phase differences between the spin species. Thus, the method according to the disclosure enables the disadvantages of the previously necessary extension of the echo spacing to be avoided.

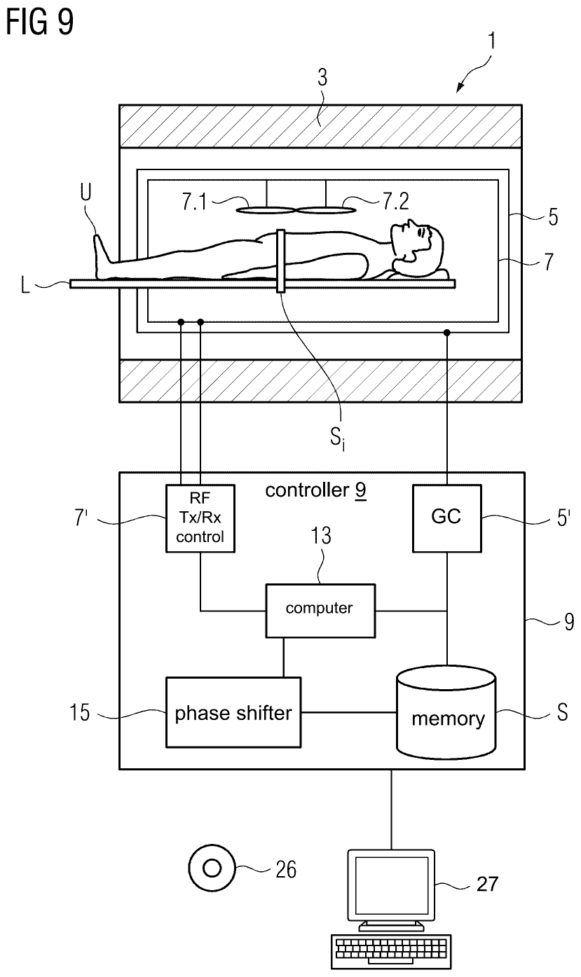

FIG. 9 is a schematic depiction of a magnetic resonance system 1 according to the disclosure. The system 1 may comprise a magnet unit 3 for generating the main magnetic field, a gradient unit 5 for generating the gradient fields, a radio-frequency unit 7 for irradiating and receiving radio-frequency signals and a control facility (controller) 9 configured to perform a method according to the disclosure and/or control the operation(s) of the system 1, which may include controlling one or more components of the system 1. The magnet unit 3, the gradient unit 5, and the radio-frequency unit 7 may collectively be referred to as a magnetic resonance (MR) scanner.

In FIG. 9, these subunits of the magnetic resonance system 1 are only shown roughly schematically. In particular, the radio-frequency unit 7 may include a plurality of subunits, for example a plurality of coils, such as the schematically shown coils 7.1 and 7.2 or more coils which can be designed either to only transmit radio-frequency signals or to only receive the triggered radio-frequency signals or to do both.

To examine an object under examination U, for example a patient or a phantom, the object can be introduced into the measurement volume of the magnetic resonance system 1 placed on a couch L. The slice or the slab Sᵢ represents an example of a target volume of the object under examination from which echo signals are to be recorded and captured as measurement data.

The control facility (controller) 9 may be configured to control the magnetic resonance system 1 and can in particular control the gradient unit 5 by means of a gradient controller 5′ and the radio-frequency unit 7 by means of a radio-frequency transmit/receive controller 7′. Herein, the radio-frequency unit 7 can comprise a plurality of channels on which signals can be transmitted or received. In an exemplary embodiment, the controller 9 may include processing circuitry configured to perform one or more functions and/or operations of the controller 9. Additionally, or alternatively, one or more components of the controller 9 may include processing circuitry configured to perform one or more respective functions and/or operations of the component(s).

The radio-frequency unit 7, together with its radio-frequency transmit/receive controller 7′, is responsible for generating and irradiating (transmitting) an alternating radio-frequency field for manipulating the spins in a region to be manipulated (for example, in slices S to be measured) of the object under examination U. Herein, the center frequency of the alternating radio-frequency field, also known as the B1 field, is generally set as close as possible to the resonance frequency of the spins to be manipulated. Deviations of the center frequency from the resonance frequency are referred to as off-resonance. To generate the B1 field, controlled currents are applied to the RF coils in the radio-frequency unit 7 by means of the radio-frequency transmit/receive controller 7′.

Furthermore, the control facility 9 may comprise a phase-shift unit (phase shifter) 15 with which RF excitation pulses according to the disclosure with desired phase shifts can be implemented by the radio-frequency transmit/receive controller 7′. The control facility 9 is embodied overall to perform a method according to the disclosure.

A computing unit (computer, processer) 13 comprised by the control facility 9 is embodied to execute all the computing operations required for the necessary measurements and determinations. Intermediate results and results required for this or ascertained in the processes can be stored in a memory unit S of the control facility 9. Herein, the units depicted are not necessarily to be understood as physically separate units, but merely represent a subdivision into functional units, which can also be realized, for example, by fewer physical units or just one physical unit.

Via an input/output I/O interface 27 of the magnetic resonance system 1, control instructions can be sent to the magnetic resonance system, for example by a user, and/or results of the control facility 9 such as, for example, image data can be displayed.

A method described herein can also be provided in the form of a computer program comprising instructions that execute the described method on a control facility 9. Likewise, a computer-readable storage medium can be provided which, when executed by a control facility 9 of a magnetic resonance system 1, cause the system to execute the described method.

1. A method for recording magnetic resonance (MR) data of an object under examination comprising spins of at least two different spin species using a magnetic resonance system, the method comprising:
irradiating a first radio-frequency (RF) excitation pulse and a sequence of at least two RF refocusing pulses to form a first echo train of at least two spin echo signals, the at least two spin echo signals being recorded and captured as measurement data in a first MR dataset, wherein the first RF excitation pulse is configured to generate a first desired phase difference between spins of a first spin species and spins of a second spin species of the at least two different spin species at the time at which the first spin echo signal of the first spin echo train is formed;
irradiating a second RF excitation pulse and a sequence of at least two RF refocusing pulses to form a second echo train of at least two spin echo signals, the spin echo signals being recorded and captured as measurement data in a second MR dataset, wherein the second RF excitation pulse is configured to generate a second desired phase difference between spins of a first spin species and spins of a second spin species of the at least two different spin species at the time at which the first spin echo signal of the second spin echo train is formed, and wherein the first desired phase difference and the second desired phase difference are different; and
storing the first MR dataset and the second MR dataset and/or further processing the first MR dataset and the second MR dataset to perform a reconstruction based on the first MR dataset and the second MR dataset.

2. The method as claimed in claim 1, wherein spin echo signals of the first echo train are recorded in first acquisition windows and captured as measurement data of the first MR dataset, and spin echo signals of the second echo train are recorded in second acquisition windows and captured as measurement data of the second MR dataset, wherein first and second acquisition windows have the same duration and the same temporal arrangement relative to the respective RF refocusing pulses.

3. The method as claimed in claim 1, wherein at least two of the RF refocusing pulses of a sequence of at least two RF refocusing pulses are a short non-selective RF refocusing pulse with a flip angle of less than 180°.

4. The method as claimed in claim 3, wherein at least two of the RF refocusing pulses of a sequence of at least two RF refocusing pulses are an RF refocusing pulse according to a SPACE (sampling perfection with application optimized contrasts using different flip angle evolutions) technique.

5. The method as claimed in claim 1, wherein the first RF excitation pulse and/or the second RF excitation pulse is a sinc pulse.

6. The method as claimed in claim 1, wherein the recording of the spin echo signals captured as measurement data in the first and second MR dataset comprises a phase-cycling method.

7. The method as claimed in claim 6, wherein the phase-cycling method generates different phases of RF refocusing pulses of the sequence of at least two RF refocusing pulses after a first RF excitation pulse, and the sequence of at least two RF refocusing pulses after a second RF excitation pulse using a numerically controlled oscillator (NCO).

8. The method as claimed in claim 7, wherein different phases are generated for the RF refocusing pulses of the sequence of at least two RF refocusing pulses after a first RF excitation pulse on the one hand and the sequence of at least two RF refocusing pulses after a second RF excitation pulse on the other such that the phases of the RF refocusing pulses of the sequence of at least two RF refocusing pulses after a first RF excitation pulse differ from the phases of the RF refocusing pulses of the sequence of at least two RF refocusing pulses after a second RF excitation pulse by a difference of the two desired phase differences.

9. The method as claimed in claim 1, wherein a time interval between an irradiated RF excitation pulse and a first spin echo signal of the corresponding echo train formed after the RF excitation pulse and/or a time interval between a first and a second spin echo signal formed after the RF excitation pulse is greater than time intervals between later spin echo signals of the echo train.

10. The method as claimed in claim 1, wherein a first RF refocusing pulse and/or a second RF refocusing pulse of a sequence of at least two RF refocusing pulses after a switched RF excitation pulse is slice-selective.

11. The method as claimed in claim 10, wherein in response to both the first and the second RF refocusing pulse of the sequence of at least two RF refocusing pulses being slice-selective, in each case, a same gradient is switched in the slice-selection direction with the first and the second RF refocusing pulse of the sequence of at least two RF refocusing pulses.

12. The method as claimed in claim 1, wherein:
a first RF refocusing pulse of a sequence of at least two RF refocusing pulses generates a flip angle of 180°; and/or
around a first RF refocusing pulse of a sequence of at least two RF refocusing pulses after an irradiated RF excitation pulse, crusher gradients are switched at least in the slice-selection direction.

13. The method as claimed in claim 1, wherein the first desired phase difference is 0° and the second desired phase difference is 180° or the first desired phase difference is 180° and the second desired phase difference is 0°.

14. The method as claimed in claim 1, wherein a first RF refocusing pulse and/or a second RF refocusing pulse of a sequence of at least two RF refocusing pulses after an irradiated RF excitation pulse is an adiabatic RF pulse.

15. A non-transitory computer-readable storage medium comprising instructions which, when executed by a controller of a magnetic resonance MR system, causes the MR system to perform the method of claim 1.

16. A magnetic resonance (MR) system comprising:
a MR scanner; and
a controller configured to:
control the MR scanner to irradiate a first radio-frequency (RF) excitation pulse and a sequence of at least two RF refocusing pulses to form a first echo train of at least two spin echo signals, the at least two spin echo signals being recorded and captured as measurement data in a first MR dataset, wherein the first RF excitation pulse is configured to generate a first desired phase difference between spins of a first spin species and spins of a second spin species of the at least two different spin species at the time at which the first spin echo signal of the first spin echo train is formed;
control the MR scanner to irradiate a second RF excitation pulse and a sequence of at least two RF refocusing pulses to form a second echo train of at least two spin echo signals, the spin echo signals being recorded and captured as measurement data in a second MR dataset, wherein the second RF excitation pulse is configured to generate a second desired phase difference between spins of a first spin species and spins of a second spin species of the at least two different spin species at the time at which the first spin echo signal of the second spin echo train is formed, and wherein the first desired phase difference and the second desired phase difference are different; and
store the first MR dataset and the second MR dataset and/or further process the first MR dataset and the second MR dataset to perform a reconstruction based on the first MR dataset and the second MR dataset.

17. The MR system as claimed in claim 16, wherein the MR scanner comprises a magnet unit, a gradient unit, and a radio-frequency unit.
